(19) United States
(12) Patent Application Publication
(10) Pub. No.: US 2010/0193029 A1
(43) Pub. Date: Aug. 5, 2010

(54) Solar Module with Encapsulated Edge

(76) Inventors: Stephen Murphy, Perrysburg, OH (US); Benyamin Buller, Sylvania, OH (US)

Correspondence Address: STEPTOE & JOHNSON LLP, 1330 CONNECTICUT AVENUE, N.W., WASHINGTON, DC, 20036, US

(21) Appl. No.: 12/636,689

(22) Filed: Dec. 11, 2009

Related U.S. Application Data
(60) Provisional application No. 61/122,571, filed on Dec. 15, 2008.

(51) Int. Cl. H01L 31/00; B29C 45/14

(52) U.S. Cl. 136/259; 264/277

(57) ABSTRACT

A solar module including a front support, back support and absorber layer are disclosed. The solar module is framed by an encapsulation frame.

### CLAIM OF PRIORITY

This application claims priority to U.S. Provisional Patent Application No. 61/122,571, filed on Dec. 15, 2008, which is incorporated by reference in its entirety.

### TECHNICAL FIELD

This invention relates to a solar module with encapsulated edge and the methods of making it.

### BACKGROUND

Solar modules have photovoltaic devices to generate electricity. Photovoltaic devices are formed between the front glass and the back glass of the solar module and edge-sealed. The tracking distance is the distance between the edge of the photovoltaic device and the outer edge of the seal. For reasons of safety, a certain tracking distance is required, which will make the peripheral portion of the solar module unusable.

### SUMMARY

In one aspect, an edge-encapsulated solar module may include a solar module and an encapsulation frame. The solar module has a back support, a front support, and an absorber layer between the front support and the back support. The encapsulation frame surrounding the solar module, where the encapsulation frame contacts an edge portion of the back support and an edge portion of the front support. The encapsulation frame may additionally contact a peripheral edge portion of a facial surface of the front support and a peripheral edge portion of a facial surface of the back support. The back and front support can include glass respectively. The encapsulation frame can include rubber, plastic, thermoplastic elastomer, or EPDM rubber.

In one aspect, a first tracking distance of solar module is a distance along a surface of the back support between an edge of the encapsulation and an edge of the absorber layer, and a second tracking distance is a distance along a surface of the front support between an edge of the encapsulation and an edge of the absorber layer. The first tracking distance and the second tracking distance can be at least 4 millimeters, about 4 millimeters to 50 millimeters, about 4 millimeters to 16 millimeters, or about 10 millimeters.

In another aspect, a method of making an edge-encapsulated solar module includes framing a photovoltaic device with an encapsulation frame contact an edge portion of each of a front support, the back support, and the photovoltaic device. The method can further include forming an absorber layer on the first support and positioning the second support on the absorber layer. The framing can include injection molding the encapsulation frame. The framing can include plastic extrusion of the encapsulation frame. The back and front support can include glass respectively. The framing can include covering a peripheral edge portion of each of the first support, the photovoltaic device, and the second support with rubber, plastic, thermoplastic elastomer, or EPDM rubber. The framing can further include a step of positioning a first edge of the encapsulation at a predetermined first tracking distance from the photovoltaic device, wherein the first tracking distance is a distance along a surface of the back support between an edge of the encapsulation and an edge of the absorber layer. The framing can further include a step of positioning a second edge of the encapsulation at a predetermined second tracking distance from the photovoltaic device, wherein the second tracking distance is a distance along a surface of the front support between an edge of the encapsulation and an edge of the absorber layer. The first tracking distance and the second tracking distance can be at least 4 millimeters, about 4 millimeters to 50 millimeters, about 4 millimeters to 16 millimeters, or about 10 millimeters.

The details of one or more embodiments are set forth in the accompanying drawings and the description below. Other features, objects, and advantages will be apparent from the description and drawings, and from the claims.

### DESCRIPTION OF DRAWINGS

FIG. 1 is a cross-sectional view of an embodiment of a solar module with encapsulated edge.

FIG. 2 is a perspective view of an embodiment of a solar module with encapsulated edge shown in FIG. 1.

FIG. 3 is a cross-sectional view of an embodiment of a solar module with encapsulated edge.

FIG. 4 is a vertical cross-sectional view taken through an injection mold of the present invention, and illustrates upper and lower mold bodies in their open position with each defining a cavity portion which in the closed position of the mold defines a mold cavity for forming the encapsulation of the instrument cover of FIG. 1.

FIG. 5 is a vertical cross-sectional view taken through the mold of FIG. 4, and illustrates the solar module positioned upon the lower mold body incident to the closing of the mold bodies.

FIG. 6 is a vertical cross-sectional view of the mold of FIGS. 4 and 5, and illustrates the mold in its closed position and a peripheral cavity defined thereby into which projects a peripheral edge of the solar module.

FIG. 7 is a vertical cross-sectional view of the mold of FIGS. 4 through 6, and illustrates thermoplastic material injected into the cavity and encapsulating an edge of the solar module to form a continuous encapsulation.

### DETAILED DESCRIPTION

To minimize the unusable peripheral portion of the solar module and maintain the certain tracking distance at the same time, the solar module is framed with an encapsulation. The tracking distance can be added up along the surface of front glass or back glass to the required distance. Therefore, the photovoltaic device can be brought closer to the edge of the glass, resulting in higher efficiency of the solar module.

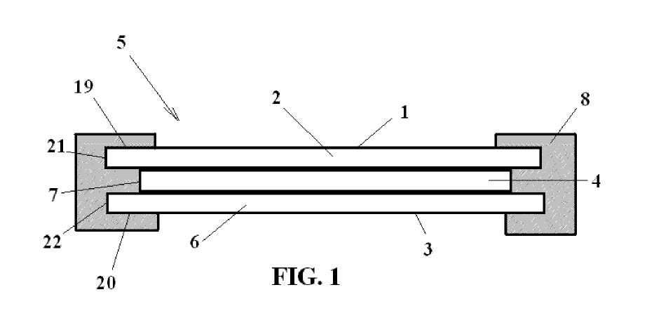

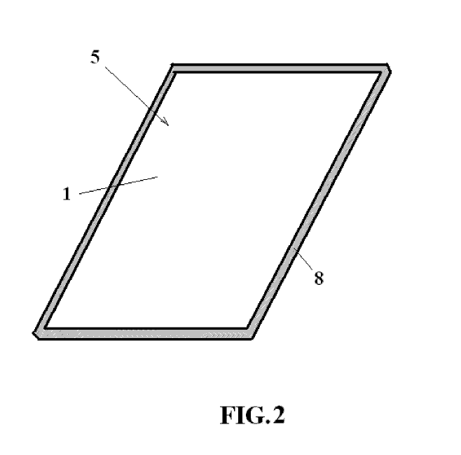

Referring to FIG. 1 and FIG. 2 as an embodiment of present invention, an edge-encapsulated solar module 5 may include a back support such as back glass 6, a front support such as front glass 2, and a photovoltaic device 4, which can include a semiconductor absorber layer that converts solar energy to electricity. The back glass 6 has a second facial surface 3 of the solar module 5. The front glass 2 has a first facial surface 1 of the solar module 5. The back glass 6 can have an edge 22. The front glass 2 can have an edge 21. The photovoltaic device 4 can be formed between the back glass 6 and the front glass 2. The photovoltaic device 4 can have an edge 7. The edge-encapsulated solar module 5 can have a peripheral encapsulation frame 8. The encapsulation frame 8 can form a frame surrounding the solar module 5. The encapsulation frame 8 can encapsulate peripheral edge portions 19 and 20 of the first facial surface 1 and the second facial surface 3 of the solar module 5 respectively. The encapsulation frame 8 can seal the edge 7 of the photovoltaic device 4. The encapsulation frame 8 can also encapsulate the edges 22 and 21 of the back glass 6 and the front glass 2 of the solar module 5 respectively. The encapsulation frame 8 may cover a minimal portion of the first facial surface 1 of the front glass 2 of the photovoltaic module 5 so as not to diminish the efficiency of the module while protecting the module edge. The encapsulation frame 8 can be made of plastic, rubber, or thermoplastic elastomer, such as ethylene-vinyl acetate (EVA). In a certain embodiment, the encapsulation frame 8 can be made of EPDM rubber.

Referring to FIG. 1, a first tracking distance is the distance from the point where encapsulation frame 8 meets second facial surface 3, along first facial surface 3 to edge 22, then along edge 22 to absorber layer edge 7. The first tracking distance created when encapsulation frame 8 is installed is a minimum distance along which an electrical charge would have to travel to reach a person or component contacting back glass 6 of solar module 5. The first tracking distance can be determined by the design of encapsulation frame 8. The first tracking distance can be at least 4 mm, for example in the range of about 4 mm to about 50 mm. The first tracking distance can be from about 4 mm to about 16 mm. The first tracking distance can be about 10 mm.

In continuing reference to FIG. 1, a second tracking distance is the distance from the point where encapsulation frame 8 meets first facial surface 1, along second facial surface 1 to edge 21, then along edge 21 to absorber layer edge 7. The second tracking distance created when encapsulation frame 8 is installed is a minimum distance along which an electrical charge would have to travel to reach a person or component contacting front glass 2 of solar module 5. The second tracking distance can be determined by the design of encapsulation frame 8. The second tracking distance can be at least 4 mm, for example in the range of about 4 mm to about 50 mm. The second tracking distance can be from about 4 mm to about 16 mm. The second tracking distance can be about 10 mm.

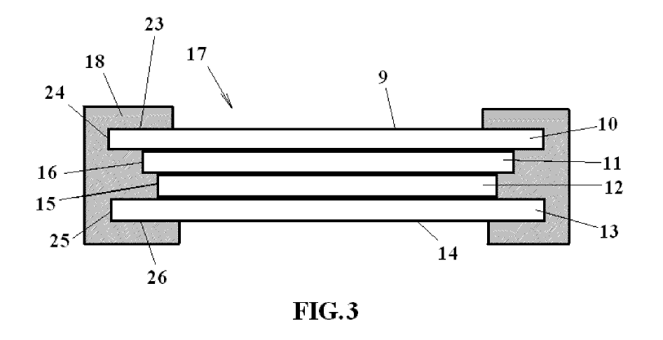

Referring to FIG. 3 as another embodiment of present invention, an edge-encapsulated solar module 17 may include a back support, such as back glass 13, a front support, such as front glass 10, a photovoltaic device 11 including a semiconductor absorber layer, and an additional layer 12. The layer 12 can be a semiconductor layer. The layer 12 can be a barrier layer, such as a SiO₂ barrier layer or a SiNₓ barrier layer. The front glass 10 has a first facial surface 9 of the solar module 17. The front glass 10 can have an edge 24. The back glass 13 has a second facial surface 14 of the solar module 17. The back glass 13 can have an edge 25. The first photovoltaic device 11 and the additional layer 12 can be formed between the back glass 13 and the front glass 10. First photovoltaic device 11 can have an edge 16. The additional layer 12 can have an edge 15. The edge-encapsulated solar module 17 can have a peripheral encapsulation frame 18. The encapsulation frame 18 can form a frame surrounding the solar module 17. The encapsulation frame 18 can cover peripheral edge portions 23 and 26 of the first surface 9 and the second surface 14 of the solar module 17 respectively. The encapsulation frame 18 can seal the edge 16 of first photovoltaic device 11 and the edge 15 of layer 12. Encapsulation frame 18 can also seal the edges 25 and 24 of the back glass 13 and the front glass 10 of the solar module 17 respectively. The encapsulation frame 18 may cover a minimal portion of the first surface 9 of the front glass 10 of photovoltaic module 17 so as not to diminish the efficiency of the module while protecting the panel edge. The encapsulation frame 18 can be made of plastic, rubber, or thermoplastic elastomer. In a certain embodiment, the encapsulation frame 18 can be made of EPDM rubber.

Referring to FIG. 3, a first tracking distance is the distance from the point where encapsulation frame 18 meets second facial surface 14, along second facial surface 14 to edge 25, then along edge 25 to additional layer edge 15, along additional layer edge 15 to photovoltaic device 11, to the absorber layer. The first tracking distance created when encapsulation frame 18 is installed is a minimum distance along which an electrical charge would have to travel to reach a person or component contacting back glass 13 of solar module 17. The first tracking distance can be determined by the design of encapsulation frame 18. The first tracking distance can be at least 4 mm, for example in the range of about 4 mm to about 50 mm. The first tracking distance can be from about 4 mm to about 16 mm. The first tracking distance can be about 10 mm.

In continuing reference to FIG. 3, a second tracking distance is the distance from the point where encapsulation frame 18 meets first facial surface 9, along first facial surface 9 to edge 24, then along edge 24 to absorber layer edge 16. The second tracking distance created when encapsulation frame 18 is installed is a minimum distance along which an electrical charge would have to travel to reach a person or component contacting front glass 10 of solar module 17. The second tracking distance can be determined by the design of encapsulation frame 18. The second tracking distance can be at least 4 mm, for example in the range of about 4 mm to about 50 mm. The second tracking distance can be from about 4 mm to about 16 mm. The second tracking distance can be about 10 mm.

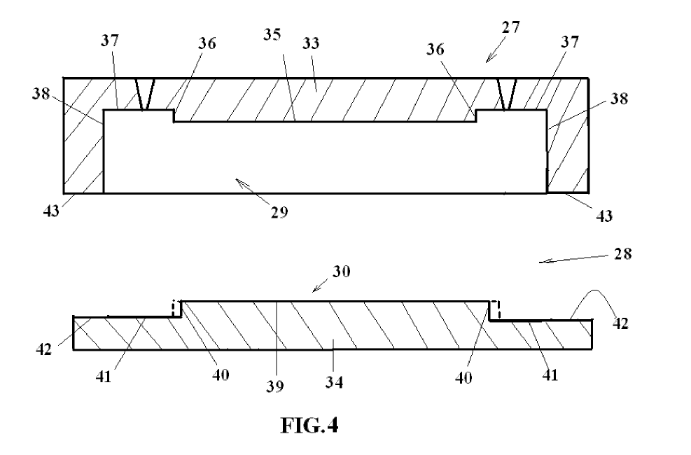

Referring to FIG. 4 through FIG. 7 as an embodiment of present invention of making edge-encapsulated solar module, the injection mold 27 includes an upper mold body 33 and a lower mold body 34 which collectively define a mold cavity 28 when the mold bodies 33, 34 are closed in a conventional manner. Injection ports, sprues, runners, etc. for injecting thermoplastic material into the cavity 28 are all conventional and are not shown in FIGS. 4 through 7 of the drawings.

The mold cavity 28 of the mold 27 includes respective upper and lower cavity portions 29, 30, respectively.

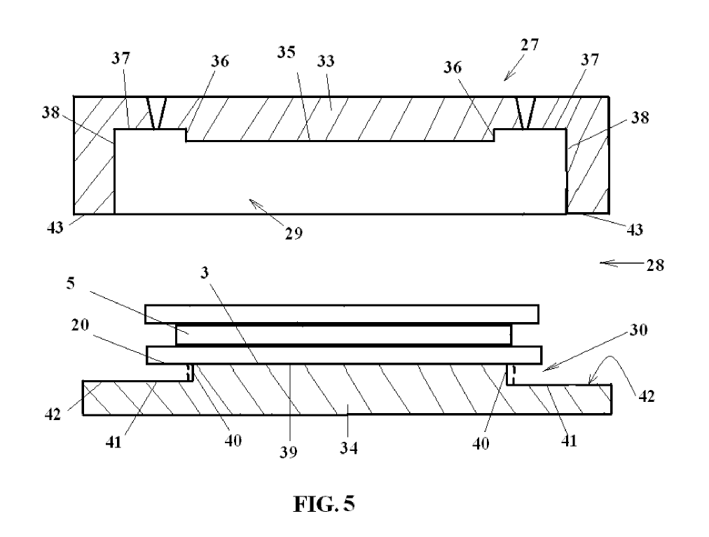

The upper cavity portion 29 of the mold cavity 28 is defined by a central quadrangular uni-planar surface 35 (FIGS. 4 and 5), an innermost peripheral surface 36, a uppermost planar surface 37 lying in a plane parallel to, but axially spaced from, the plane of the central quadrangular surface 35, and an outermost peripheral surface 38 which merges with a peripheral parting surface 43.

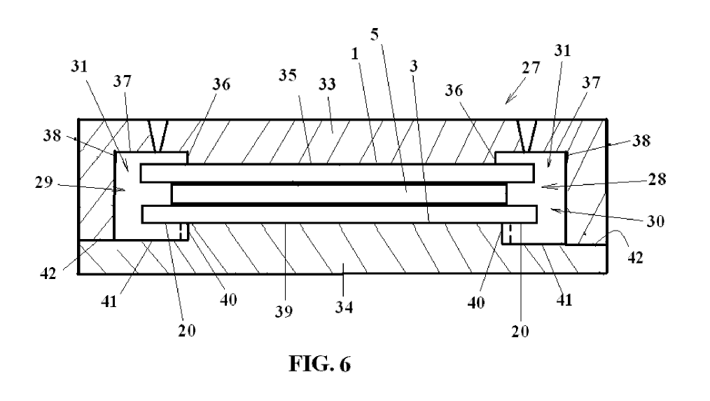

The cavity portion 30 is defined by a central quadrangular uni-planar surface 39 (FIGS. 4 and 5) in substantially spaced opposing relationship to the central quadrangular uni-planar surface 35 of the cavity portion 29, an innermost peripheral surface 40, and a lowermost planar surface 41 lying in a plane parallel to, but axially spaced from, the plane of the central quadrangular surface 39. The planar surface 41 has a peripheral portion 42 which abuts the parting surface 43 of the upper mold body 33 when the upper and lower mold bodies 33, 34, respectively, are closed (FIG. 6). In certain embodiments, the peripheral surface 40 can be designed to include diametrically opposite bayonet lugs/slots, preferably spaced 90 degrees from each other or conventional threads, but no matter the character of the peripheral surface 40, the function thereof is to permit the rapid attachment and detachment of the solar module 5 respectively to and from the injection mold 27 in a conventional manner.

In the open position of the mold bodies 33, 34 (FIG. 4), the solar module 5 is seated atop and upon the central quadrangular uni-planar surface 39 of the mold body 34 in the manner illustrated in FIG. 5 with the peripheral edge portion 20 projecting an equal distance beyond the peripheral surface 40. The mold bodies 33, 34 are closed in the manner illustrated in FIG. 6. In the closed position, the solar module 5 is clamped between surfaces 35, 39 and a peripheral cavity 31 is defined. Such closing techniques are conventional in the art, and suffice it to say that the mold bodies 33, 34 are brought to the closed position of the solar module 5 such that a peripheral portion of the cavity 28 is in part set off and defined by the peripheral edge portion 20 of the solar module 5 projecting therein, as is clearly illustrated in FIG. 6.

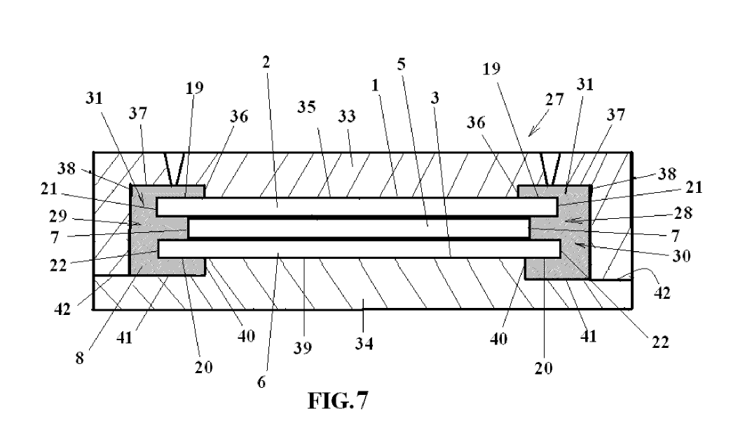

As is best illustrated in FIG. 7 of the drawings, thermoplastic material is injected into the peripheral cavity 31 resulting in the formation of the encapsulation frame 8 which covers peripheral edge portions 20 and 19 of the second facial surface 3 and the first facial surface 1 of the solar module 5 respectively. The encapsulation frame 8 seals the edge 7 of the photovoltaic device 4. The encapsulation frame 8 also seals the edges 22 and 21 of the back glass 6 and the front glass 2 of the solar module 5 respectively. Upon solidification of the encapsulation frame 8, the solar module 5 is framed. Upon the opening of the mold bodies 33, 34, the edge-encapsulated solar module 5 can remain seated upon the mold body 34 (FIG. 7) or can be withdrawn therefrom.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. An edge-encapsulated solar module comprising:
a solar module comprising a back support, a front support, and an absorber layer between the front support and the back support; and
an encapsulation frame surrounding the solar module, wherein the encapsulation frame contacts an edge portion of the back support and an edge portion of the front support.

2. The solar module of claim 1, wherein the encapsulation frame additionally contacts a peripheral edge portion of a facial surface of the front support and a peripheral edge portion of a facial surface of the back support.

3. The solar module of claim 1, wherein the front support comprises a glass.

4. The solar module of claim 1, wherein the back support comprises a glass.

5. The solar module of claim 1, wherein the encapsulation frame comprises a rubber.

6. The solar module of claim 1, wherein the encapsulation frame comprises a plastic.

7. The solar module of claim 1, wherein a first tracking distance is a distance along a surface of the back support between an edge of the encapsulation and an edge of the absorber layer, and a second tracking distance is a distance along a surface of the front support between an edge of the encapsulation and an edge of the absorber layer.

8. The solar module of claim 7, wherein the first tracking distance is at least 4 millimeters.

9. The solar module of claim 7, wherein the second tracking distance is at least 4 millimeters.

10. A method of making an edge-encapsulated solar module comprising:
framing a photovoltaic device with an encapsulation frame contacting an edge portion of each of a front support, a back support, and the photovoltaic device.

11. The method of claim 10, further comprising forming an absorber layer on the first support and positioning the second support on the absorber layer.

12. The method of claim 10, wherein framing includes injection molding the encapsulation frame.

13. The method of claim 10, wherein framing includes plastic extrusion of the encapsulation frame.

14. The method of claim 10, wherein framing includes covering a peripheral edge portion of each of the first support, the photovoltaic device, and the second support with rubber.

15. The method of claim 10, wherein framing includes covering a peripheral edge portion of each of the first support, the photovoltaic device, and the second support with plastic.

16. The method of claim 10, wherein framing further comprises the step of positioning a first edge of the encapsulation at a predetermined first tracking distance from the photovoltaic device, wherein the first tracking distance is a distance along a surface of the back support between an edge of the encapsulation and an edge of the absorber layer.

17. The method of claim 10, wherein framing further comprises the step of positioning a second edge of the encapsulation at a predetermined second tracking distance from the photovoltaic device, wherein the second tracking distance is a distance along a surface of the front support between an edge of the encapsulation and an edge of the absorber layer.

18. The method of claim 10, wherein the first tracking distance is at least 4 millimeters.

19. The method of claim 10, wherein the second tracking distance is at least 4 millimeters.
